(19) United States
(12) Patent Application Publication
(10) Pub. No.: US 2009/0316032 A1
(43) Pub. Date: Dec. 24, 2009

(54) IMAGE SENSOR AND METHOD OF MANUFACTURING IMAGE SENSOR

(75) Inventors: Kaori Misawa, Kaizu-shi (JP); Mamoru Arimoto, Ogaki-shi (JP); Hayato Nakashima, Anpachi-gun (JP); Ryu Shimizu, Mizuho-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/479,325

(22) Filed: Jun. 5, 2009

(30) Foreign Application Priority Data
Jun. 20, 2008 (JP) 2008-161252

(51) Int. Cl. H04N 5/335; H01L 21/28

(52) U.S. Cl. 348/308; 438/90; 257/E21.21; 348/E05.091

(57) ABSTRACT

An image sensor includes an increase portion for impact-ionizing and increasing signal charges, a charge increasing electrode for applying a voltage increasing the signal charges to the increase portion and an insulating film provided between the charge increasing electrode and the increase portion, wherein the insulating film includes a first insulating film made of a thermal oxide film and a second insulating film made of an oxide film, formed on the first insulating film.

### CROSS-REFERENCE TO RELATED APPLICATIONS

The priority application number JP2008-161252, Image Sensor, Jun. 20, 2008, Kaori Misawa, Mamoru Arimoto, Hayato Nakashima, Ryu Shimizu, upon which this patent application is based is hereby incorporated by reference.

### BACKGROUND OF THE INVENTION

1. Field of the Invention

The present invention relates to an image sensor and a method of manufacturing an image sensor, and more particularly, it relates to an image sensor comprising an increase portion for impact-ionizing and increasing signal charges and a method of manufacturing an image sensor.

2. Description of the Background Art

An image sensor comprising an increase portion for impact-ionizing and increasing electrons (signal charges) and a method of manufacturing an image sensor are known in general.

A CMOS image sensor comprising an increase portion for impact-ionizing and increasing electrons (signal charges) and a charge increasing electrode for applying a voltage for increasing electrons to the increase portion is disclosed in general. In this CMOS image sensor, a gate insulating film having a constant thickness between the increase portion and the charge increasing electrode is formed. A charge transfer electrode for applying a voltage transferring electrons is formed on a surface of the gate insulating film in addition to the charge increasing electrode.

### SUMMARY OF THE INVENTION

An image sensor according to a first aspect of the present invention comprises an increase portion for impact-ionizing and increasing signal charges, a charge increasing electrode for applying a voltage increasing the signal charges to the increase portion and an insulating film provided between the charge increasing electrode and the increase portion, wherein the insulating film includes a first insulating film made of a thermal oxide film and a second insulating film made of an oxide film, formed on the first insulating film.

A method of manufacturing an image sensor according to a second aspect of the present invention comprises steps of forming an increase portion for impact-ionizing and increasing signal charges, forming an insulating film on a surface of the increase portion and forming a charge increasing electrode for applying a voltage increasing the signal charges to the increase portion on a surface of the insulating film, wherein the step of forming the insulating film includes a step of forming a first insulating film made of a thermal oxide film by thermal oxidation and a step of forming a second insulating film made of an oxide film by oxidation on the first insulating film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of an image sensor according to a first embodiment of the present invention;

FIG. 2 is a sectional view of a pixel provided on the image sensor according to the first embodiment;

FIG. 3 is an enlarged sectional view of the pixel provided on the image sensor according to the first embodiment;

FIG. 4 is a plan view of the pixel provided on the image sensor according to the first embodiment;

FIG. 5 is a circuit diagram of the pixel provided on the image sensor according to the first embodiment;

FIG. 6 is a potential diagram for illustrating an electron transferring operation of the pixel provided on the image sensor according to the first embodiment;

FIG. 7 is a signal waveform diagram for illustrating an electron transferring operation of the pixel provided on the image sensor according to the first embodiment;

FIG. 8 is a potential diagram for illustrating the electron transferring operation of the pixel provided on the image sensor according to the first embodiment;

FIG. 9 is a signal waveform diagram for illustrating the electron transferring operation of the pixel provided on the image sensor according to the first embodiment;

FIG. 10 is a diagram illustrating an experiment conducted for a structure including a gate insulating film made of an oxide film and a nitride film;

FIG. 11 is a diagram illustrating the experiment conducted for the structure including the gate insulating film made of the oxide film and the nitride film;

FIG. 12 is a sectional view of a pixel provided on an image sensor according to a second embodiment of the present invention; and

FIG. 13 is an enlarged sectional view of the pixel provided on the image sensor according to the second embodiment of the present invention.

### DESCRIPTION OF THE PREFERRED EMBODIMENTS

Embodiments of the present invention will be hereinafter described with reference to the drawings.

### First Embodiment

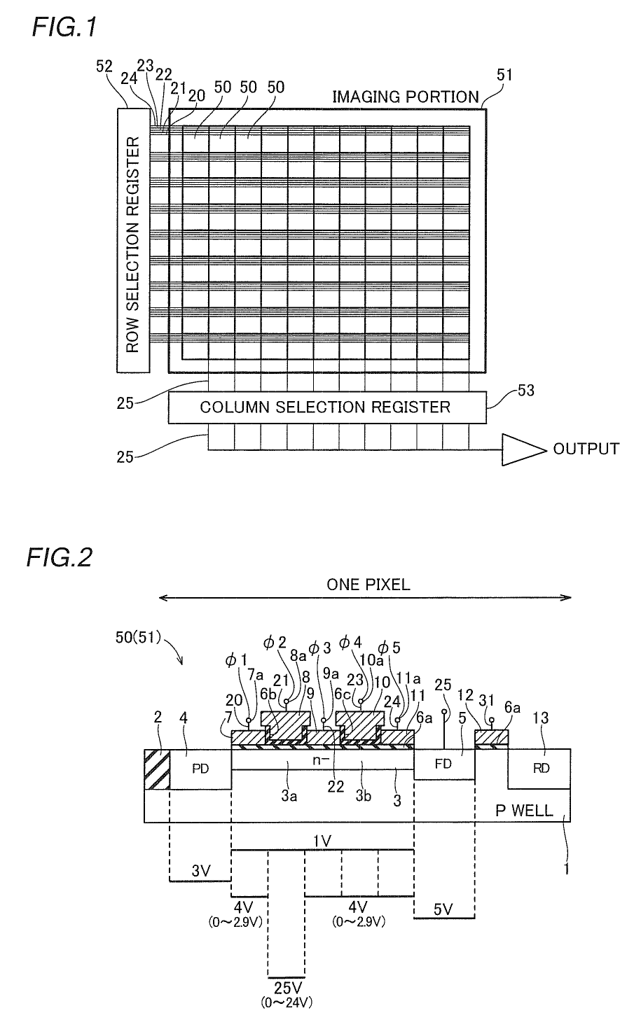

The CMOS image sensor comprises an imaging portion 51 including a plurality of pixels 50 arranged in the form of a matrix, a row selection register 52 and a column selection register 53, as shown in FIG. 1.

As to the sectional structure of the pixels 50 of the CMOS image sensor, element isolation regions 2 for isolating the pixels 50 from each other are formed on a surface of a p-type well region 1 formed on a surface of an n-type silicon substrate (not shown), as shown in FIG. 2. On a surface of the p-type well region 1 provided with each of the pixels 50 enclosed with the corresponding element isolation regions 2, a photodiode (PD) portion 4 and a floating diffusion (FD) region 5 consisting of an n-type impurity region are formed at a prescribed interval, to hold a transfer channel 3 consisting of an n⁻-type impurity region therebetween. The transfer channel 3 is an example of the “charge transfer region” in the present invention.

The PD portion 4 has a function of generating electrons in response to the quantity of incident light and storing the generated electrons. The PD portion 4 is formed to be adjacent to the corresponding element isolation region 2 as well as to the transfer channel 3. The FD region 5 has a function of holding a charge signal formed by transferred electrons and converting the charge signal to a voltage. The FD region 5 is formed to be adjacent to the corresponding element isolation region 2 as well as to the transfer channel 3. Thus, the FD region 5 is formed to be opposed to the PD portion 4 through the transfer channel 3.

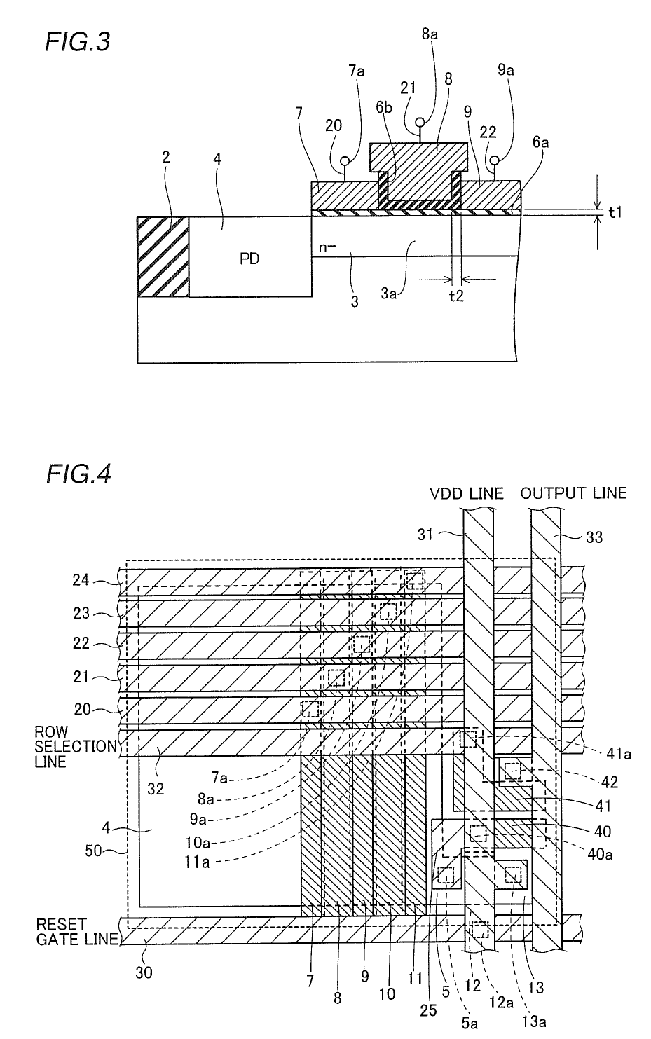

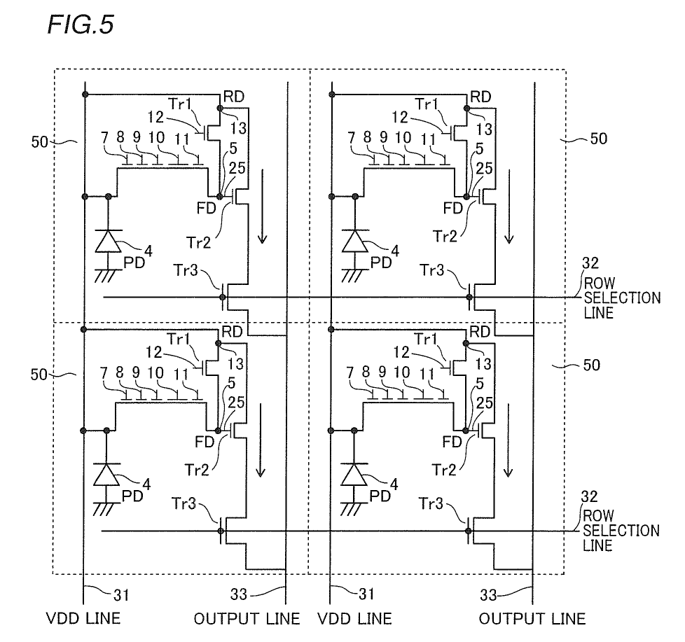

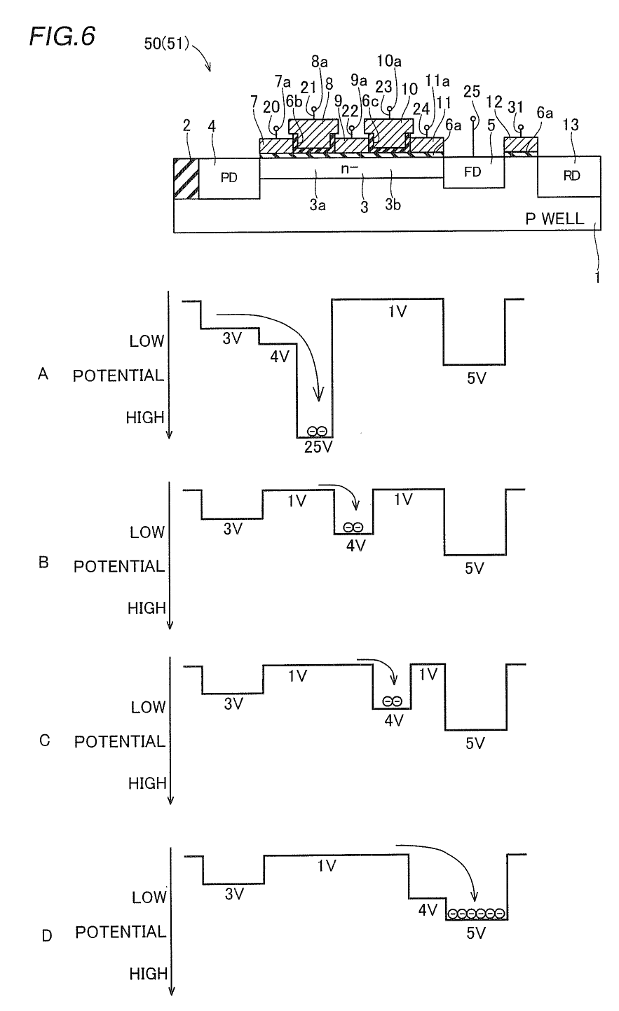

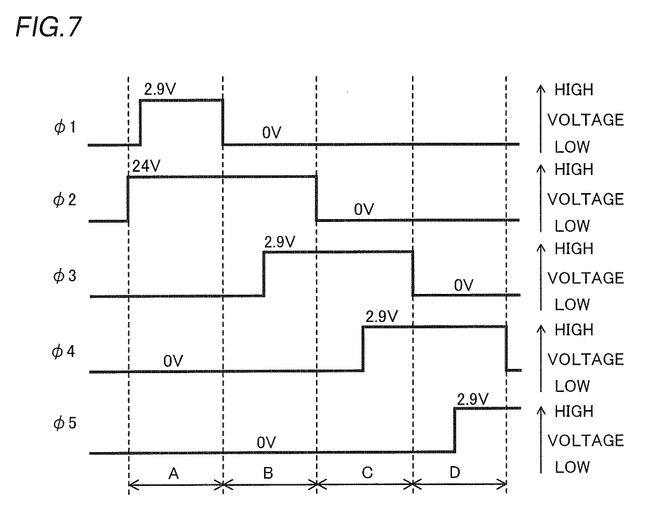

A first insulating film 6a made of a thermal oxide film (SiO₂ film) formed by thermally oxidizing the surface of a silicon (Si) substrate (the surface of the transfer channel 3), having a function as a gate insulating film is formed on a surface of the transfer channel 3. As shown in FIG. 3, the first insulating film 6a has a thickness t1 of at most about 35 nm. As shown in FIG. 2, a transfer gate electrode 7, a multiplier gate electrode 8, a transfer gate electrode 9, a storage gate electrode 10 and a read gate electrode 11 are formed on a surface of the first insulating film 6a in this order from a side of the PD portion 4 toward a side of the FD region 5. The storage gate electrode 10 is an example of the “charge storage electrode” in the present invention. The transfer gate electrodes 7 and 9 are examples of the “charge transfer electrode” in the present invention. The transfer gate electrode 7 is formed between the PD portion 4 and the multiplier gate electrode 8. The multiplier gate electrode 8 and the storage gate electrode 10 are formed in T-shapes to extend above the adjacent electrodes on both sides, respectively. The T-shape includes a state where a top of the T-shape is recessed (concaved). The read gate electrode 11 is formed between the storage gate electrode 10 and the FD region 5. The read gate electrode 11 is formed to be adjacent to the FD region 5.

An upper portion of the multiplier gate electrode 8 extends toward the transfer gate electrodes 7 and 9 to overlap the adjacent transfer gate electrodes 7 and 9 in plan view. An upper portion of the storage gate electrode 10 extends toward the transfer gate electrode 9 and the read gate electrode 11 to overlap the adjacent transfer gate electrode 9 and the adjacent read gate electrode 11 in plan view.

A reset gate electrode 12 is formed on a surface of another first insulating film 6a to hold the FD region 5 between the reset gate electrode 12 and the read gate electrode 11. A reset drain region 13 is formed to hold the reset gate electrode 12 between the reset drain region 13 and the FD region 5. An electron multiplying portion 3a is provided on a portion of the transfer channel 3 located under the multiplier gate electrode 8, and an electron storage portion 3b is provided on a portion of the transfer channel 3 located under the storage gate electrode 10. The multiplier gate electrode 8 and the electron multiplying portion 3a are examples of the “charge increasing electrode” and the “increase portion” in the present invention, respectively.

A second insulating film 6b is formed between a lower surface of the multiplier gate electrode 8 and an upper surface of the first insulating film 6a, between side surfaces of the multiplier gate electrode 8 and the transfer gate electrodes 7 and 9. The second insulating film 6b has a thickness t2 of about 40 nm larger than the thickness of the first insulating film 6a and is made of an oxide film of SiO₂ formed by CVD (chemical vapor deposition). As shown in FIG. 3, an insulating film of about 75 nm is formed under the multiplier gate electrode 8 by the silicon thermal oxide film and the second insulating film 6b. As shown in FIG. 2, a third insulating film 6c is formed on a lower surface and both side surfaces of the storage gate electrode 10. More specifically, the third insulating film 6c is formed between the lower surface of the storage gate electrode 10 and the upper surface of the first insulating film 6a and between the side surfaces of the storage gate electrode 10 and the transfer and read gate electrodes 9 and 11.

The second insulating film 6b provided between the opposed side surfaces of the multiplier gate electrode 8 and the transfer gate electrodes 7 and 9 is provided up to lower surface portions of portions, formed to extend toward the transfer gate electrodes 7 and 9, of the upper portion of the multiplier gate electrode 8. The third insulating film 6c provided between the opposed side surfaces of the storage gate electrode 10 and the transfer and read gate electrodes 9 and 11 is provided up to the lower surface portions of the portions, formed to extend toward the transfer gate electrode 9 and the read gate electrode 11, of the upper portion of the storage gate electrode 10.

The second insulating film 6b and the third insulating film 6c provided on the multiplier gate electrode 8 and the storage gate electrode 10 respectively are formed through the same step. Thus, the thickness t2 of the second insulating film 6b and the thickness of the third insulating film 6c are the same. The thickness of the third insulating film 6c is larger than the thickness t1 of the first insulating film 6a. This third insulating film 6c is formed by the oxide film of SiO₂ formed by CVD, similarly to the second insulating film 6b.

The second insulating film 6b and the third insulating film 6c are not provided between the transfer channel 3 and the transfer gate electrodes 7 and 9 and the read gate electrode 11, while the first insulating film 6a is provided between the transfer channel 3 and the transfer gate electrodes 7 and 9 and the read gate electrode 11.

As shown in FIGS. 2 and 4, wiring layers 20, 21, 22, 23 and 24 supplying clock signals φ1, φ2, φ3, φ4 and φ5 for voltage control are electrically connected to the transfer gate electrode 7, the multiplier gate electrode 8, the transfer gate electrode 9, the storage gate electrode 10 and the read gate electrode 11 through contact portions 7a, 8a, 9a, 10a and 11a respectively. The wiring layers 20, 21, 22, 23 and 24 are formed every row (see FIG. 1), and electrically connected to the transfer gate electrode 7, the multiplier gate electrode 8, the transfer gate electrode 9, the storage gate electrode 10 and the read gate electrode 11 of all of the pixels 50 forming each row respectively. A signal line 25 for extracting a signal through a contact portion 5a is electrically connected to the FD region 5.

As shown in FIGS. 4 and 5, each pixel 50 includes a reset transistor Tr1 including the transfer gate electrode 7, the multiplier gate electrode 8, the transfer gate electrode 9, the storage gate electrode 10, the read gate electrode 11 and the reset gate electrode 12, an amplification transistor Tr2 and a pixel selection transistor Tr3. A reset gate line 30 is connected to the reset gate electrode 12 of the reset transistor Tr1 through the contact portion 12a, to supply a reset signal. A drain (reset drain 13) of the reset transistor Tr1 is connected to a power supply potential (VDD) line 31 through another contact portion 13a. The FD region 5 constituting sources of the reset transistor Tr1 and the read gate electrode 11 and a gate 40 of the amplification transistor Tr2 are connected with each other through the contact portions 5a and 40a by the signal line 25. A drain of the pixel selection transistor Tr3 is connected to a source of the amplification transistor Tr2. A row selection line 32 and an output line 33 are connected to a gate 41 and a source of the pixel selection transistor Tr3 through the contact portions 41a and 42 respectively.

In the CMOS image sensor according to the first embodiment, the number of wires and the number of transistors for decoding are reduced by the aforementioned circuit structure. Thus, the overall CMOS image sensor can be downsized. According to this circuit structure, the read gate electrode 11 is on-off controlled every row, while the remaining gate electrodes other than the read gate electrode 11 are simultaneously on-off controlled with respect to the overall pixels 50.

When ON-state (high-level) clock signals φ1, φ3, φ4 and φ5 are supplied to the transfer gate electrode 7, the transfer gate electrode 9, the storage gate electrode 10 and the read gate electrode 11 through the wiring layers 20, 22, 23 and 24 respectively, voltages of about 2.9 V are applied to the transfer gate electrode 7, the transfer gate electrode 9, the storage gate electrode 10 and the read gate electrode 11, as shown in FIG. 2.

The portions of the transfer channel 3 located under the transfer gate electrodes 7 and 9, the storage gate electrode 10 and the read gate electrode 11 respectively are controlled to potentials of about 4 V when the voltages of about 2.9 V are applied to the transfer gate electrodes 7 and 9, the storage gate electrode 10 and the read gate electrode 11 respectively (high-level signals are supplied).

When an ON-state (high-level) clock signal φ2 is supplied to the multiplier gate electrode 8 from the wiring layer 21, a voltage of about 24 V is applied to the multiplier gate electrode 8. Thus, the portion of the transfer channel 3 located under the multiplier gate electrode 8 is controlled to a high potential of about 25 V when the ON-state (high-level) clock signal φ2 is supplied to the multiplier gate electrode 8.

When OFF-state (low-level) clock signals φ1, φ2, φ3, φ4 and φ5 are supplied to the transfer gate electrode 7, the multiplier gate electrode 8, the transfer gate electrode 9, the storage gate electrode 10 and the read gate electrode 11, voltages of about 0 V are applied to the transfer gate electrode 7, the multiplier gate electrode 8, the transfer gate electrode 9, the storage gate electrode 10 and the read gate electrode 11. At this time, regions of the transfer channel 3 corresponding to the portions located under the transfer gate electrode 7, the multiplier gate electrode 8, the transfer gate electrode 9, the storage gate electrode 10 and the read gate electrode 11 respectively are controlled to potentials of about 1 V.

When the ON-state signal is supplied to the transfer gate electrode 7, the transfer gate electrode 7 has a function of transferring electrons generated by the PD portion 4 to the electron multiplying portion 3a located on the portion of the transfer channel 3 located under the multiplier gate electrode 8 through the portion of the transfer channel 3 located under the transfer gate electrode 7. The portion of the transfer channel 3 located under the transfer gate electrode 7 has a function as an isolation barrier dividing the PD portion 4 and the portion of the transfer channel 3 located under the multiplier gate electrode 8 (electron multiplying portion 3a) from each other when the OFF-state signal is supplied to the transfer gate electrode 7.

The multiplier gate electrode 8 is supplied with the ON-state signal, so that a high voltage (about 25 V) is applied to the electron multiplying portion 3a located on the portion of the transfer channel 3 located under the multiplier gate electrode 8. Then the speed of electrons transferred to the electron multiplying portion 3a located under the multiplier gate electrode 8 is increased by a high electric field generated in the electron multiplying portion 3a and the electrons are multiplied by impact-ionization with atoms in the impurity region.

The transfer gate electrode 9 has a function of transferring electrons between the portion (electron multiplying portion 3a) of the transfer channel 3 located under the multiplier gate electrode 8 and the electron storage portion 3b provided on the portion of the transfer channel 3 located under the storage gate electrode 10 by supplying the ON-state signal to the transfer gate electrode 9. When the OFF-state signal is supplied to the transfer gate electrode 9, the transfer gate electrode 9 functions as a charge transfer barrier for suppressing transfer of electrons between the electron multiplying portion 3a located under the multiplier gate electrode 8 and the electron storage portion 3b located under the storage gate electrode 10.

When the ON-state signal is supplied to the read gate electrode 11, the read gate electrode 11 has a function of transferring electrons stored in the portion of the transfer channel 3 located under the storage gate electrode 10 (electron storage portion 3b) to the FD region 5. When the OFF-state signal is supplied to the read gate electrode 11, the read gate electrode 11 has a function of dividing the portion (electron storage portion 3b) of the transfer channel 3 located under the storage gate electrode 10 and the FD region 5.

The FD region 5 is controlled to a potential of about 5 V. The reset drain region 13 is controlled to a potential of about 5 V and has a function as an ejecting portion of electrons held in the FD region 5.

The electron transferring operation will be now described. When light is incident upon the PD portion 4, electrons are generated in the PD portion 4 by photoelectric conversion. In a period A, a voltage of about 2.9 is applied to the transfer gate electrode 7 after a voltage of about 24 V is applied to the multiplier gate electrode 8. Thus, electrons generated by the PD portion 4 (about 3 V) are transferred to the electron multiplying portion 3a (about 25 V) under the multiplier gate electrode 8 through the portion of the transfer channel 3 located under the transfer gate electrode 7 (about 4V). At this time, the speed of electrons is increased on the electron multiplying portion 3a and the electrons are multiplied by impact-ionization with atoms in the impurity region.

In a period B, a voltage of about 0 is applied to the multiplier gate electrode 8 in a state of applying a voltage of about 2.9 V to the transfer gate electrode 9. Thus, electrons are transferred from the electron multiplying portion 3a (about 1 V) under the multiplier gate electrode 8 to the portion (about 4 V) of the transfer channel 3 located under the transfer gate electrode 9.

In a period C, a voltage of about 0 is applied to the transfer gate electrode 9 in a state of applying a voltage of about 2.9 V to the storage gate electrode 10. Thus, electrons are transferred from the portion (about 1 V) of the transfer channel 3 located under the transfer gate electrode 9 to the electron storage portion 3b (about 4 V) under the storage gate electrode 10.

In a period D, a voltage of about 0 is applied to the storage gate electrode 10 in a state of applying a voltage of about 2.9 V to the read gate electrode 11. Thus, the electrons are transferred to the FD region 5 (about 5 V) through the portion (about 4 V) of the transfer channel 3 located under the read gate electrode 11. Thereafter, a voltage of about 0 V is applied to the read gate electrode 11, so that the portion of the transfer channel 3 located under the read gate electrode 11 is controlled to a potential of about 1 V. Thus, the electron transferring operation is completed.

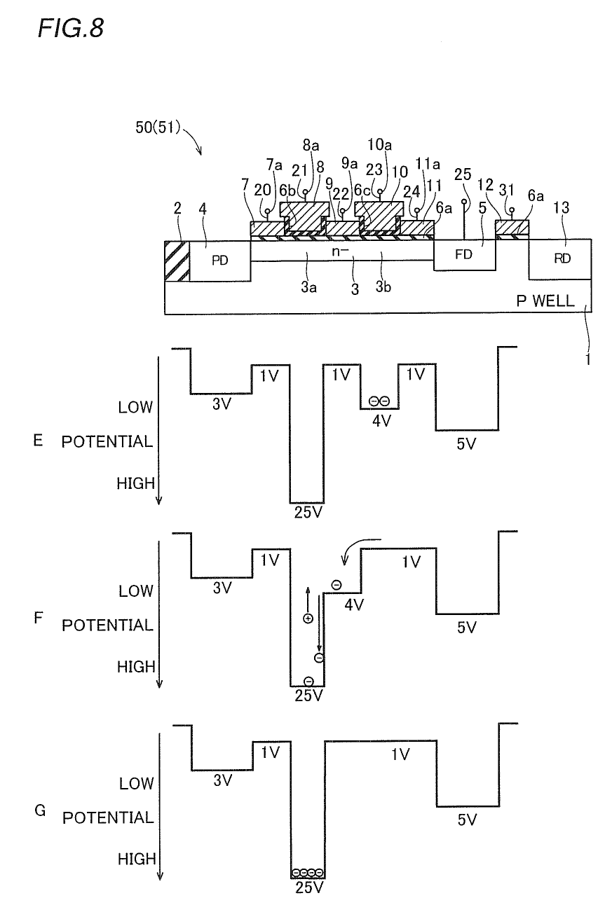

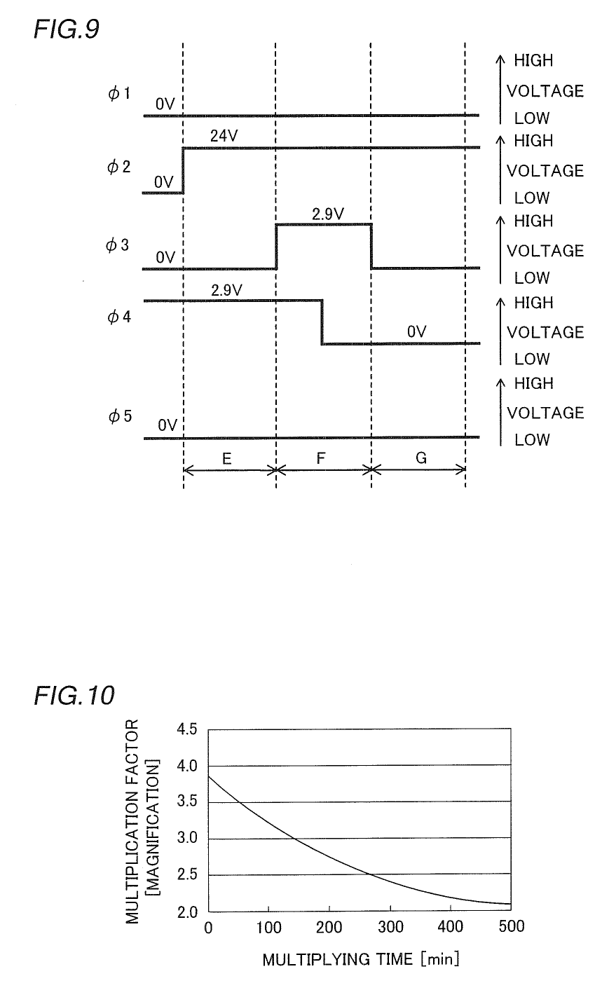

The electron multiplying operation will be now described. In the electron multiplying operation, operations in periods E to G shown in FIGS. 8 and 9 are performed from a state where the operations in the aforementioned periods A to C have been performed. In other words, the electron multiplying portion 3a located under the multiplier gate electrode 8 is controlled to a potential of about 25 V in the period E, and the portion of the transfer channel 3 located under the transfer gate electrode 9 is controlled to a potential of about 4 V in the period F. Thereafter, the potential of the electron storage portion 3b located under the storage gate electrode 10 is controlled to about 1 V, so that the electrons stored in the electron storage portion 3b are transferred to the electron multiplying portion 3a (about 25 V) located under the multiplier gate electrode 8 through the portion (about 4 V) of the transfer channel 3 located under the transfer gate electrode 9. Thus, electrons are multiplied. In a period G, the transfer gate electrode 9 is brought into an OFF-state, thereby completing the multiplying operation. The electrons multiplied by performing the aforementioned operation in the period D from the state in the period G are transferred to the FD region 5.

The electron transferring operation is performed between the electron multiplying portion 3a and the electron storage portion 3b a plurality of times (about 400 times, for example), thereby multiplying electrons transferred from the PD portion 4 to about 2000 times. The charge signal formed by the electrons thus multiplied and stored is read as a voltage signal through the FD region 5 and the signal line 25 by the aforementioned read operation.

According to the first embodiment, as hereinabove described, the gate insulating film formed by the first insulating film 6a and the second insulating film 6b is provided between the electron multiplying portion 3a and the multiplier gate electrode 8, whereby the gate insulating film is formed by two layers and hence the withstand voltage of the multiplier gate electrode 8 can be further improved. Accordingly, a higher voltage for increasing electrons in the electron multiplying portion 3a can be applied to the multiplier gate electrode 8. Thus, the electrons can be multiplied by desired magnification, and hence a high-definition image can be obtained.

According to the first embodiment, as hereinabove described, the second insulating film 6b (SiO₂ film) made of the oxide film is formed by CVD dissimilarly to the first insulating film 6a (SiO₂ film) made of thermal oxide film, whereby the second insulating film 6b (SiO₂ film) having a thickness larger than the first insulating film 6a (SiO₂ film) made of the thermal oxide film can be easily formed.

According to the first embodiment, as hereinabove described, the second insulating film 6b is formed to cover the lower surface and the side surfaces of the multiplier gate electrode 8, whereby not only the withstand voltage between the lower surface of the multiplier gate electrode 8 and the upper surface of the first insulating film 6a but also the withstand voltage between the transfer gate electrode 7 and the transfer gate electrode 9 adjacent to the both side of the multiplier gate electrode 8 can be improved with respect to the high voltage applied to the multiplier gate electrode 8.

According to the first embodiment, as hereinabove described, the thickness t2 of the second insulating film 6b is larger than the thickness t1 of the first insulating film 6a, whereby the withstand voltage of the multiplier gate electrode 8 can be further improved due to the larger thickness of the second insulating film 6b.

According to the first embodiment, as hereinabove described, the CMOS image sensor comprises the third insulating film 6c made of the oxide film which is different from the thermal oxide film provided between the storage gate electrode 10 and the first insulating film 6a, whereby the gate insulating film is formed by two layers and hence the withstand voltage of the storage gate electrode 10 can be improved.

According to the first embodiment, as hereinabove described, the third insulating film 6c formed on the first insulating film 6a is formed to cover the lower surface and side surfaces of the storage gate electrode 10, whereby insulation properties can be improved between the storage gate electrode 10 and the transfer channel 3 and between the storage gate electrode 10 and the transfer and read gate electrodes 9 and 11 adjacent to the both sides of the storage gate electrode 10.

According to the first embodiment, as hereinabove described, the thickness of the third insulating film 6c is larger than the thickness of the first insulating film 6a, whereby the withstand voltage of the storage gate electrode 10 can be improved due to the larger thickness of the third insulating film 6c.

According to the first embodiment, as hereinabove described, the first insulating film 6a includes the SiO₂ film of the thermal oxide film, and the third insulating film 6c includes the SiO₂ film of the oxide film formed by CVD, whereby the third insulating film 6c (SiO₂ film) having a thickness larger than the first insulating film 6a (SiO₂ film) of the thermal oxide film can be easily formed.

According to the first embodiment, as hereinabove described, the second insulating film 6b made of the oxide film is provided between the opposed side surfaces of the multiplier gate electrode 8 and the transfer gate electrodes 7 and 9, and the third insulating film 6c of the oxide film is provided between the opposed side surfaces of the storage gate electrode 10 and the transfer and read gate electrodes 9 and 11. Thus, insulating properties can be improved between the multiplier gate electrode 8 and the transfer gate electrodes 7 and 9 adjacent to the both sides of the multiplier gate electrode 8 and insulating properties can be improved between the storage gate electrode 10 and the transfer and read gate electrodes 9 and 11 adjacent to the both sides of the storage gate electrode 10.

In the aforementioned first embodiment, the gate insulating film under the multiplier gate electrode 8 is formed in a two-layer structure of the oxide film including the first insulating film 6a and the second insulating film 6b. A case where the gate insulating film under the multiplier gate electrode is formed by an oxide film and a nitride film will be demonstrated.

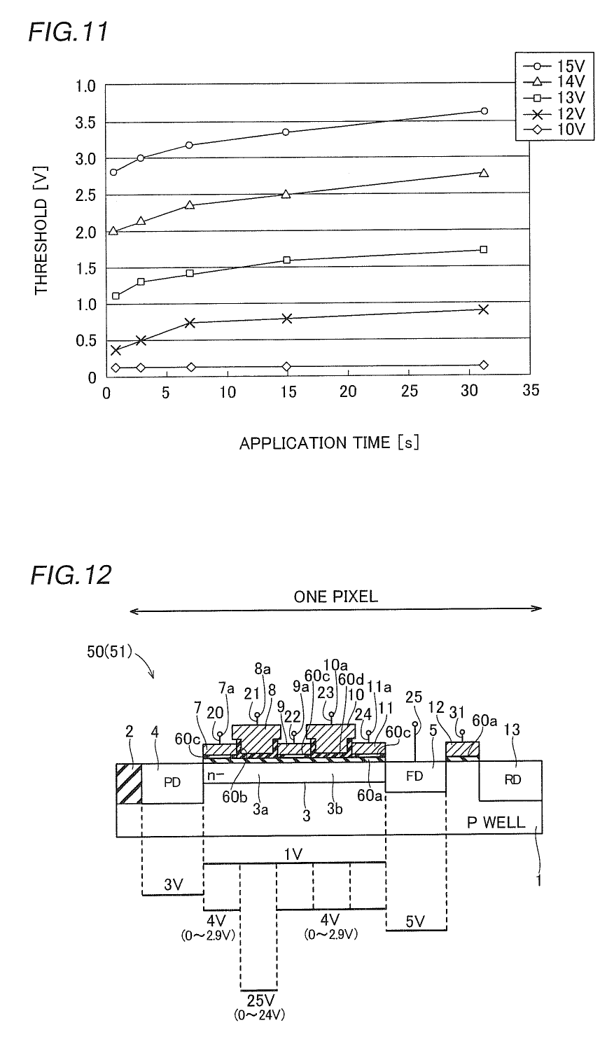

When a multiplying operation similar to the aforementioned embodiment is performed in a state where the gate insulating film under the multiplier gate electrode is in a multilayer structure of the oxide film and the nitride film, the multiplication factor of the electrons is reduced as multiplying time is increased, as shown in FIG. 10. This shows that the multiplication factor is gradually reduced as compared with the multiplying operation initially performed even when the similar multiplying operation is performed. In a case where the voltage applied to the multiplier gate electrode is changed, a voltage applied to the multiplier gate electrode is at least 12 V at which electrons are multiplied, a voltage (threshold) at which the multiplier gate electrode is brought into an ON-state is increased as voltage application time is increased, as shown in FIG. 11. When a voltage applied to the multiplier gate electrode is at most 10 V at which electrons are not multiplied, on the other hand, a voltage (threshold) at which the multiplier gate electrode is brought into an ON-state is constant regardless of the voltage application time.

These phenomena conceivably occur due to the nitride film included in the gate insulating film under the multiplier gate electrode. Accordingly, it is conceivable that the portion in contact with at least the electron multiplying portion 3a in the gate insulating film corresponding to the multiplier gate electrode is preferably formed by the oxide film (SiO₂ film). Further, it is conceivable that the gate insulating film corresponding to the multiplier gate electrode is preferably formed by the oxide film (SiO₂ film) containing no nitride film.

### Second Embodiment

According to the second embodiment, nitride films 60c are formed between a transfer gate electrode 7, a transfer gate electrode 9 and a read gate electrode 11 and a first insulating film 60a. The nitride films 60c are examples of the “fourth insulating film” in the present invention.

As shown in FIG. 12, the first insulating film 60a made of a thermal oxide film (SiO₂ film) functioning as a gate insulating film is formed on a surface of the transfer channel 3. A second insulating film 60b and a third insulating film 60d made of oxide films (SiO₂ films) formed by CVC, functioning as gate insulating films are arranged between lower surfaces of a multiplier gate electrode 8 and a storage gate electrode 10 and an upper surface of the first insulating film 60a and between both side surfaces of the multiplier gate electrode 8 and the storage gate electrode 10 and side surfaces of the transfer gate electrode 7, the transfer gate electrode 9 and the read gate electrode 11, similarly to the first embodiment. The nitride films (SiN films) 60c formed by CVD are arranged between the transfer gate electrode 7, the transfer gate electrode 9 and the read gate electrode 11 and the first insulating film 60a respectively.

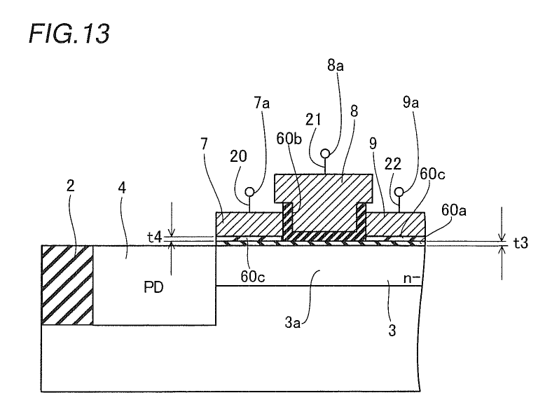

As shown in FIG. 13, the first insulating film 60a has a thickness t3 of at least about 10 nm and not more than about 20 nm and the nitride film 60c has a thickness t4 of about 30 nm. The nitride film 60c has a function as an etching stopper for patterning each gate electrode by etching. Further, the nitride film 60c has a function of suppressing threshold change caused by gate bird's beak of the transfer gate electrode 7, the transfer gate electrode 9 and the read gate electrode 11.

The remaining structure and operation of the second embodiment are similar to those of the first embodiment.

According to the second embodiment, as hereinabove described, even when the nitride films 60c are provided between the transfer gate electrode 7, the transfer gate electrode 9 and the read gate electrode 11 and the first insulating film 60a, the gate insulating film including the first insulating film 60a and the second insulating film 60b made of the oxide films (SiO₂ films) is provided between the multiplier gate electrode 8 and the electron multiplying portion 3a, so that a withstand voltage can be improved as compared with a case where the gate insulating film is formed by a single layer having a constant thickness, and hence a higher voltage can be applied to the electron multiplying portion 3a.

The remaining effects of the second embodiment are similar to those of the first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first and second embodiments is applied to the active CMOS image sensor amplifying signal charges in each pixel as an exemplary image sensor, the present invention is not restricted to this but is also applicable to a passive CMOS image sensor not amplifying signal charges in each pixel.

While the second insulating film is formed by the oxide film (SiO₂ film) formed by CVD in each of the aforementioned first and second embodiments, the present invention is not restricted to this but the second insulating film may be an oxide film, such as a thermal oxide film, for example, other than the oxide film formed by CVD.

While the first insulating film and the second insulating film are formed by the oxide film made of the SiO₂ film in each of the aforementioned first and second embodiments, the present invention is not restricted to this but the first insulating film and the second insulating film may be formed by oxide films other than the SiO₂ film.

While the gate insulating film under the multiplier gate electrode and the storage gate electrode are formed in the two-layer structure including the first insulating film and the second insulating film in each of the aforementioned first and second embodiments, the present invention is not restricted to this but they may be formed in a multiplayer structure including at least three-layers.

While the multiplier gate electrode 8 is formed between the transfer gate electrode 7 and the transfer gate electrode 9 and the storage gate electrode 10 is formed between the transfer gate electrode 9 and the read gate electrode 11 in each of the aforementioned first and second embodiments, the present invention is not restricted to this but the storage gate electrode 10 may be formed between the transfer gate electrode 7 and the transfer gate electrode 9 and the multiplier gate electrode 8 may be provided between the transfer gate electrode 9 and the read gate electrode 11.

While the transfer channel 3, the PD portion 4 and the FD region 5 are formed on the surface of the p-type well region 1 formed on the surface of the n-type silicon substrate (not shown) in each of the aforementioned first and second embodiments, the present invention is not restricted to this but the transfer channel 3, the PD portion 4 and the FD region 5 may be formed on a surface of a p-type silicon substrate.

While electrons are employed as signal charges in each of the aforementioned first and second embodiments, the present invention is not restricted to this but holes may alternatively be employed as signal charges by entirely reversing the conductivity type of the substrate impurity and the polarities of the applied voltages.

What is claimed is:

1. An image sensor comprising:
an increase portion for impact-ionizing and increasing signal charges;
a charge increasing electrode for applying a voltage increasing the signal charges to said increase portion; and
an insulating film provided between said charge increasing electrode and said increase portion, wherein
said insulating film includes a first insulating film made of a thermal oxide film and a second insulating film made of an oxide film, formed on said first insulating film.

2. The image sensor according to claim 1, wherein
said second insulating film includes an oxide film different in type from said thermal oxide film.

3. The image sensor according to claim 2, wherein
said first insulating film includes an SiO₂ film, and
said second insulating film includes an SiO₂ film made of an oxide film different in type from said SiO₂ film.

4. The image sensor according to claim 1, wherein
said second insulating film is so formed as to cover a lower surface and a side surface of said charge increasing electrode.

5. The image sensor according to claim 1, wherein
a thickness of said second insulating film is larger than a thickness of said first insulating film.

6. The image sensor according to claim 1, further comprising:
a charge storage electrode for storing charges, formed at a prescribed interval from said charge increasing electrode; and
a third insulating film made of an oxide film different in type from said thermal oxide film provided between said charge storage electrode and said first insulating film formed to extend up to a lower surface portion of said charge storage electrode.

7. The image sensor according to claim 6, wherein
said third insulating film formed on said first insulating film is so formed as to cover a lower surface and a side surface of said charge storage electrode.

8. The image sensor according to claim 6, wherein
a thickness of said third insulating film is larger than a thickness of said first insulating film.

9. The image sensor according to claim 6, wherein
said first insulating film includes an SiO₂ film, and
said third insulating film includes an SiO₂ film made of an oxide film different in type from said SiO₂ film.

10. The image sensor according to claim 6, further comprising:
a charge transfer electrode for transferring charges, provided between said charge increasing electrode and said charge storage electrode; and
a charge transfer region for transferring charges, provided under a surface of said first insulating film formed to extend up to a lower surface portion of said charge transfer electrode and including said increase portion, wherein
said second insulating film is not provided between said charge transfer electrode and said charge transfer region, while said first insulating film is provided between said charge transfer electrode and said charge transfer region.

11. The image sensor according to claim 10, further comprising a fourth insulating film provided between said charge transfer electrode and said first insulating film.

12. The image sensor according to claim 11, wherein
said fourth insulating film provided between said charge transfer electrode and said first insulating film includes an SiN film different from said first insulating film.

13. The image sensor according to claim 10, wherein
said second insulating film is provided between opposed side surfaces of said charge increasing electrode and said charge transfer electrode, and
said third insulating film is provided between opposed side surfaces of said charge storage electrode and said charge transfer electrode.

14. The image sensor according to claim 13, wherein
an upper portion of said charge increasing electrode and an upper portion of said charge storage electrode extend toward said charge transfer electrode so as to overlap with adjacent said charge transfer electrode in plan view,
said second insulating film provided between the opposed side surfaces of said charge increasing electrode and said charge transfer electrode is provided up to a lower surface portion of a portion, formed to extend toward said charge transfer electrode, of said upper portion of said charge increasing electrode, and
said third insulating film provided between the opposed side surfaces of said charge storage electrode and said charge transfer electrode is provided up to a lower surface portion of a portion, formed to extend toward said charge transfer electrode, of said upper portion of said charge storage electrode.

15. A method of manufacturing an image sensor, comprising steps of:
forming an increase portion for impact-ionizing and increasing signal charges;
forming an insulating film on a surface of said increase portion; and
forming a charge increasing electrode for applying a voltage increasing the signal charges to said increase portion on a surface of said insulating film, wherein
said step of forming said insulating film includes a step of forming a first insulating film made of a thermal oxide film by thermal oxidation and a step of forming a second insulating film made of an oxide film by oxidation on said first insulating film.

16. The method of manufacturing an image sensor, according to claim 15, wherein
said step of forming said second insulating film includes a step of forming an oxide film different in type from said thermal oxide film by CVD.

17. The method of manufacturing an image sensor, according to claim 16, wherein
said step of forming said first insulating film includes a step of forming an SiO₂ film by thermal oxidation, and
said step of forming said second insulating film includes a step of forming an SiO₂ film by CVD.

18. The method of manufacturing an image sensor, according to claim 15, wherein
said step of forming said second insulating film includes a step of forming said second insulating film to cover a lower surface and a side surface of said charge increasing electrode.

19. The method of manufacturing an image sensor, according to claim 15, wherein
said step of forming said second insulating film includes a step of forming said second insulating film to have a thickness larger than a thickness of said first insulating film.

20. The method of manufacturing an image sensor, according to claim 15, wherein
said step of forming said first insulating film includes a step of forming said first insulating film to extend outward beyond the side surface of said charge increasing electrode, further comprising steps of:
forming a charge storage electrode on a surface of said first insulating film at a prescribed interval from said charge increasing electrode; and
forming a third insulating film made of an oxide film between said charge storage electrode and said first insulating film by oxidation, wherein
said step of forming said third insulating film and said step of forming said second insulating film are performed by the same step.
